(19) United States
(12) Patent Application Publication
(10) Pub. No.: US 2026/0240023 A1
(43) Pub. Date: Aug. 13, 2026

(54) MULTI-LAYER LINER FOR STRESS BUFFERING IN GLASS VIAS

(71) Applicant: Applied Materials, Inc., Santa Clara, CA (US)

(72) Inventors: Dong Kil YIM, Pleasanton, CA (US); Changling LI, San Jose, CA (US); Tae Kyung WON, San Jose, CA (US); Lai ZHAO, Campbell, CA (US); Helinda NOMINANDA, San Jose, CA (US); Wenhui LI, Santa Clara, CA (US); Soo Young CHOI, Fremont, CA (US)

(21) Appl. No.: 19/534,137

(22) Filed: Feb. 9, 2026

Related U.S. Application Data
(60) Provisional application No. 63/756,534, filed on Feb. 10, 2025.

(51) Int. Cl. H10W 70/685; H10W 70/05; H10W 70/63; H10W 70/692

(52) U.S. Cl. CPC H10W 70/686; H10W 70/095; H10W 70/635; H10W 70/692

(57) ABSTRACT

Embodiments of the present disclosure are directed to liners for glass vias and method for forming multi-layer liners for stress buffering in glass vias. In an embodiment, the method includes depositing a first sublayer over a surface of a substrate comprising a glass core and a via extending therethrough, in which the first sublayer comprises a compressive stress between about -500 MPa and about -1500 MPa. The method also includes depositing a second sublayer over the first sublayer inside the via, and a third sublayer over the second sublayer. The second sublayer comprises a Young’s modulus between about 1 GPa and about 15 GPa, and the third sublayer comprises a stress between about -100 MPa and about -800 MPa compressive stress.

### RELATED APPLICATIONS

This application claims the benefit of and priority to U.S. Provisional Application No. 63/756,534 filed February 10, 2025, which is herein incorporated in its entirety by reference for all purposes.

### BACKGROUND

### Field

Embodiments of the present disclosure are directed to the field of semiconductor device manufacturing, and more particularly to methods of packaging semiconductor devices.

### Description of the Related Art

The ever-increasing demand for miniaturized semiconductor devices has led to continuously increasing circuit densities and decreasing device sizes. As a result of the continued scaling of these devices, integrated circuits have evolved into complex three-dimensional (3D) devices that can include millions of transistors, capacitors, and resistors on a single chip. 3D integration allows a significant reduction in device footprint and enables ever shorter and faster connections between that device's sub-components, thus improving processing capabilities and speed thereof. These capabilities make 3D integration a desirable technique for the semiconductor device industry to keep pace with Moore's law.

Currently, the 3D device technology landscape includes several general classes of 3D integration processes that vary in the level at which the devices are partitioned into different pieces. Such 3D integration processes include stacked integrated circuit (“SIC”) technology, system-in-package (“SiP”) technology, and system-on-chip (“SOC”) technology. Despite the promise of 3D device technology, current approaches to 3D integration face many challenges. One of the major drawbacks associated with current 3D integration techniques is thermal management. As a result of the varying thermal properties of materials utilized during conventional packaging manufacturing processes, coefficient of thermal expansion (“CTE”) mismatch may occur between deposited molding compounds (e.g., vias, interconnects) and semiconductor device components (e.g., semiconductor dies, substrates, wafers, interposers, and the like). The existence of CTE mismatch, particularly between substrates and deposited material or film layers can lead to structural deterioration, such as cracking or interfacial delamination.

Accordingly, there is a need in the art for improved methods of forming reconstituted substrates for packaging schemes.

### SUMMARY

Embodiments of the present disclosure are directed to methods of forming vias in glass substrates. In an embodiment, a method of forming a multi-layer liner in a substrate is provided. The method includes depositing a first sublayer over a surface of the substrate. The substrate includes a glass core and a via extending therethrough. The first sublayer is disposed over the sidewalls of the via and comprises a compressive stress between about -500 MPa and about -1500 MPa. The method also includes depositing a second sublayer over the first sublayer inside the via and depositing a third sublayer over the second sublayer. The second sublayer comprises a Young’s modulus between about 1 GPa and about 15 GPa, and the third sublayer comprises a stress between about -100 MPa and about -800 MPa compressive stress.

In another embodiment, a method of forming a multi–layer liner in a substrate is provided. The method includes depositing a first portion of a first sublayer over a top surface of the substrate, the substrate comprising a via extending between the top surface and a bottom surface of a glass core. The substrate is then flipped, and a second portion of the first sublayer is deposited over the bottom surface of the substrate and in the via. The first sublayer comprises a compressive stress between about -500 MPa and about -1500 MPa. After the first sublayer is formed, a first portion of a second sublayer is deposited over the second portion of the first sublayer. The substrate is then flipped, and a second portion of the second sublayer is deposited over the first portion of the first sublayer on the substrate and in the via. The second sublayer comprises a Young’s modulus between about 1 GPa and about 15 GPa. After the second sublayer is formed, the method continues with depositing a first portion of a third sublayer over the second portion of the second sublayer on the substrate, flipping the substrate, and then depositing a second portion of the third sublayer over the first portion of the second sublayer on the substrate and in the via. The third sublayer comprises a compressive stress between about -100 MPa and about -800 MPa.

In a further embodiment, a semiconductor substrate is provided. The semiconductor substrate includes a glass core having a via extending therethrough. The substrate also includes a multi-layer liner comprising: a first sublayer disposed over an interior surface of the via, wherein the first sublayer comprises a compressive stress between about -500 MPa and about -1500 MPa. The multi-layer liner also includes a second sublayer disposed over the first sublayer, and a third sublayer disposed over the second sublayer. The second sublayer comprises a Young’s modulus between about 1 GPa and about 15 GPa, and the third sublayer comprises a compressive stress between about -100 MPa and about -800 MPa. The substrate also includes a conductive interconnect structure formed in the via, wherein the multi-layer liner is disposed between the glass core and the conductive interconnect structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a through glass via formed in a substrate, according to certain embodiments;

FIG. 2 is a flow diagram of a method for forming a multi-layer liner in a via, according to certain embodiments;

FIGS. 3A-3G are schematic, cross-sectional views of a substrate being processed using the method in FIG. 2, according to certain embodiments;

FIG. 4 is a schematic cross-sectional view of a portion of a multi-layer liner formed in a substrate, according to certain embodiments;

FIG. 5 is a schematic cross-sectional view of a blind glass via formed in a substrate, according to certain embodiments;

FIG. 6 is a flow diagram of a method for forming a multi-layer liner in a via, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to 3D packaging applications incorporating glass-based substrates, for example, glass-based panel level packaging with glass interposers. Interest in glass for Integrated Circuit (IC) packaging and interposer applications has accelerated in recent years, due to its favorable mechanical and electrical properties compared to current advanced materials. In three-dimensional (3D) packaging applications, in addition to through silicon vias (TSV) used for a silicon substrate, glass substrates may also be used. In accordance with one or more embodiments described herein, the present disclosure is directed to the fabrication of through glass vias (TGV) in glass substrates. For example, in cases where glass is used for manufacturing of sensors as a capping wafer, TGVs are utilized for providing a vertical connection through a glass substrate. These TGVs are the vertical electrical interconnection between the electronic circuits of the overlying electronic circuit substrate, interconnect lines in the interposer, and the outside environment to connect the electronic circuits. In other embodiments, for example as applied to use of a glass interposer, the formation of a TGV is essential for packaging applications.

In an embodiment, TGVs are formed in a glass core substrate, such as a glass interposer, by patterning the glass substrate to form through holes or openings in the glass substrate. Thereafter, a conducting interconnect material, such as a metal, is deposited in the through holes to form the TGV. In an embodiment, copper is used as the conducting interconnect material for forming the TGV. In such an embodiment, copper (Cu) is deposited in the through holes to form the TGV extending through the glass substrate. One of the difficulties in implementing Cu as the interconnect material of a TGV in a glass substrate is the CTE mismatch between the two components. Glass generally has a low CTE (3 ppm/K < Glass_{CTE} < 10 ppm/k) while Cu has a high CTE (16~17 ppm/K). Fundamentally, CTE is a material property that represents a change in volume of a material per unit temperature change. In thin film systems, a CTE mismatch between adjacent layers in systems can lead to structural deterioration such as interfacial delamination or cracking. As the fabrication of copper metallization contains numerous processing steps that expose the interconnects to high temperatures, the mismatch in CTE between copper and the other materials that comprise the back-end-of-line levels (e.g., the glass core substrate) can induce significant tensile stress in the metallization due to thermal cycling. In particular, plastic deformation generated within Cu can result in tensile stress gradients that can double the total stress near the metallic film interface relative to the bulk stress in the film. If the stress of the layers of the Cu interconnect is higher than the stress of the glass core substrate, then the glass core substrate can crack. CTE mismatch can also affect device reliability as it can also cause delamination of the layers of Cu interconnect structure (e.g., Cu seed layer and/or Cu) in response to compressive stress from when the glass core substrate and the Cu is heated and cooled. Conventional single layer liners with low Young’s modulus have been used for buffering stress at the metallic film interface. However, such liners can conversely have other problems such as poor adhesion with the glass core substrate and Cu interconnect structure, outgassing at elevated temperatures, and tensile stress growth.

The present disclosure provides a multi-layer liner for buffering the mechanical stress between the layers of the interconnect structure and the core glass substrate and corresponding methods of fabricating the multi-layer liner. Without being bound by theory, in certain embodiments, the multi-layer liner is configured to absorb and distribute the mechanical stress from physical changes of the layers of the interconnect structure caused by temperature change, while still being strong enough to be compressible and adhere to surfaces of the glass substrate and the interconnect structure. Moreover, the multi-layer liner of the present disclosure can be formed with reduced or no outgassing at elevated temperatures throughout the entire fabrication process.

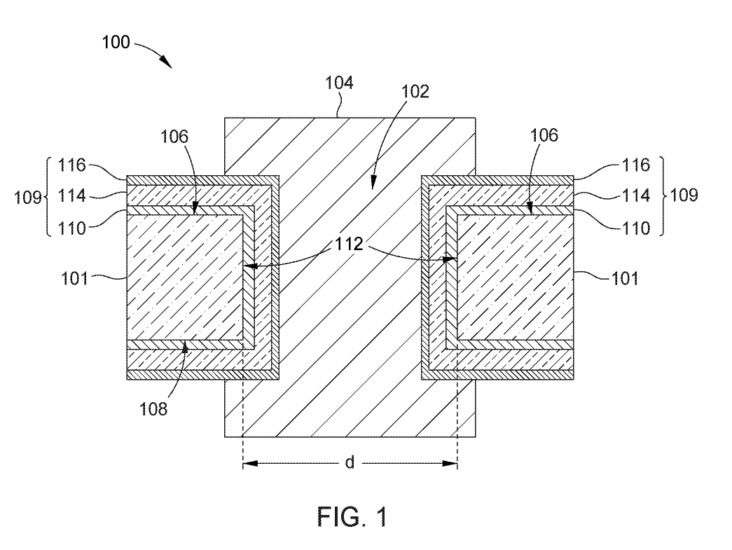

FIG. 1 is a schematic cross-sectional view of a substrate 100 illustrating a multi-layer liner and an interconnect structure formed in a via extending therethrough, according to certain embodiments. Here, the substrate 100 includes a glass core 101 having a via 102 formed therein and an interconnect structure 104 extending therethrough. In some embodiments, the via 102 (shown filled with the interconnect structure 104) is a vertical interconnect access or hole extending through the substrate 100. In other embodiments, the via 102 may be a blind via extending partially through the substrate 100 (as shown in FIG. 5). In an embodiment, the via 102 extends from an opening in a first surface 106 of the glass core 101 to an opening in a second surface 108 of the glass core 101 on the opposite side of the substrate 100. In some embodiments, a diameter d of the via 102 may be between about 5 microns and about 150 microns.

In some embodiments, the interconnect structure 104 is a vertical conductive copper (Cu) structure for electrically connecting layers above and below the glass core 101. In such an embodiment, the substrate 100 includes a multi-layer liner 109 lining the via 102 between the glass core 101 and the interconnect structure 104. In some embodiments, the multi-layer liner 109 includes a first sublayer 110, a second sublayer 114, and a third sublayer 116. The first sublayer 110 is in contact with an interior surface 112 of the via 102 along the glass core 101. The second sublayer 114 is disposed between the first sublayer 110 and the third sublayer 116 which is in contact with the interconnect structure 104.

In some embodiments, the first sublayer 110 can be any film having a compressive stress between about -500 MPa and about -1500 MPa when deposited on the glass core 101. For example, in an embodiment, the first sublayer 110 may be a film layer made of silicon nitride (SiNx), silicon oxynitride (SiON), silicon carbide (SiC), silicon oxide (SiO), a metal oxide (e.g., AlOx), or combinations thereof. In an embodiment, the first sublayer 110 may be a SiN₁₃ film layer having a compressive stress of about -500 MPa.

In some embodiments, the second sublayer 114 is a SiOC film layer having a Young’s modulus between about 1 and about 15 GPa when deposited on the first sublayer 110. In some embodiments, the second sublayer 114 is formed with a tensile stress of about 50 MPa and a compressive stress of about -100 MPa. The relatively low Young’s modulus of the second sublayer 114 enables the second sublayer 114 to absorb and distribute mechanical stress between the glass core 101 and the interconnect structure 104, thereby preventing the glass core 101 from cracking or layers of the interconnect structure 104 from delaminating due to internal stress buildup.

In some embodiments, the third sublayer 116 can be any film having a compressive stress between about -100 MPa and about -800 MPa when deposited on the second sublayer 114. For example, in an embodiment, the third sublayer 116 may be a film layer made of silicon nitride (SiNx), silicon oxynitride (SiON), silicon carbide (SiC), silicon oxide (SiO), a metal oxide (e.g., AlOx), or combinations thereof.

In some embodiments, a thickness of the multi-layer liner 109 may be optimized to effectively buffer the glass core 101 and the interconnect structure 104 without affecting the overall device performance. Accordingly, in some embodiments, a thickness of the first sublayer 110 and the third sublayer 116 may be dependent on a thickness of the second sublayer 114. For example, the second sublayer 114 may be formed with a thickness between about .5 microns and about 5 microns, such between about 1 micron and about 3 microns, or between about 3 microns and about 4 microns. In some embodiments, the first sublayer 110 may be formed with a thickness between about 5% and about 15% of the thickness of the second sublayer 114. In some embodiments, the third sublayer 116 may also be formed with a thickness between about 5% and about 15% of the thickness of the second sublayer 114.

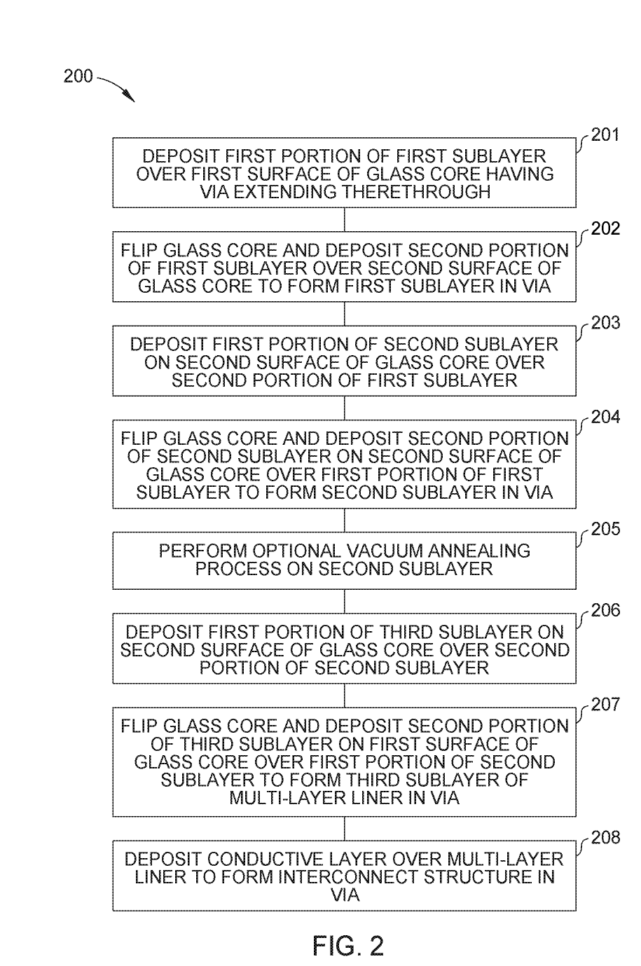

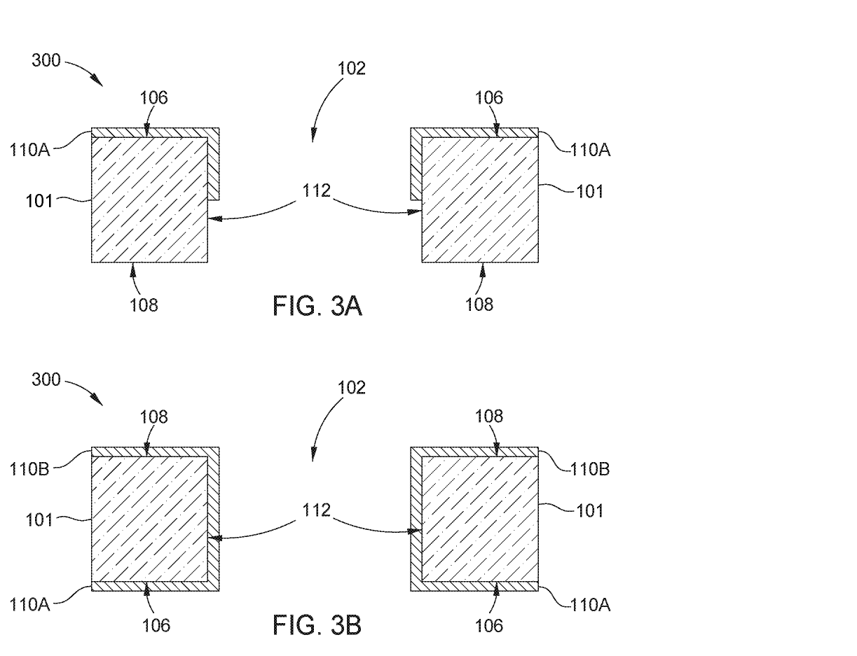

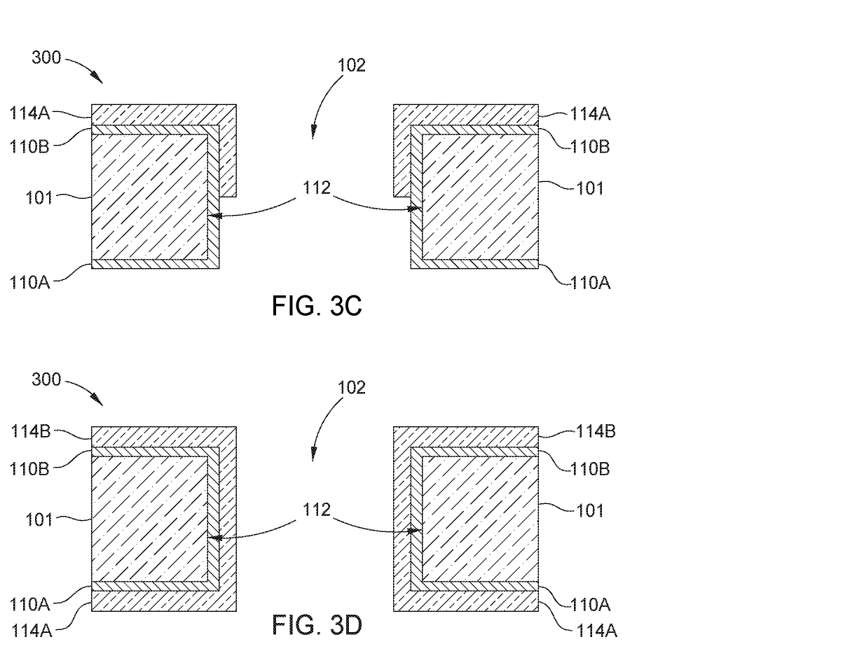

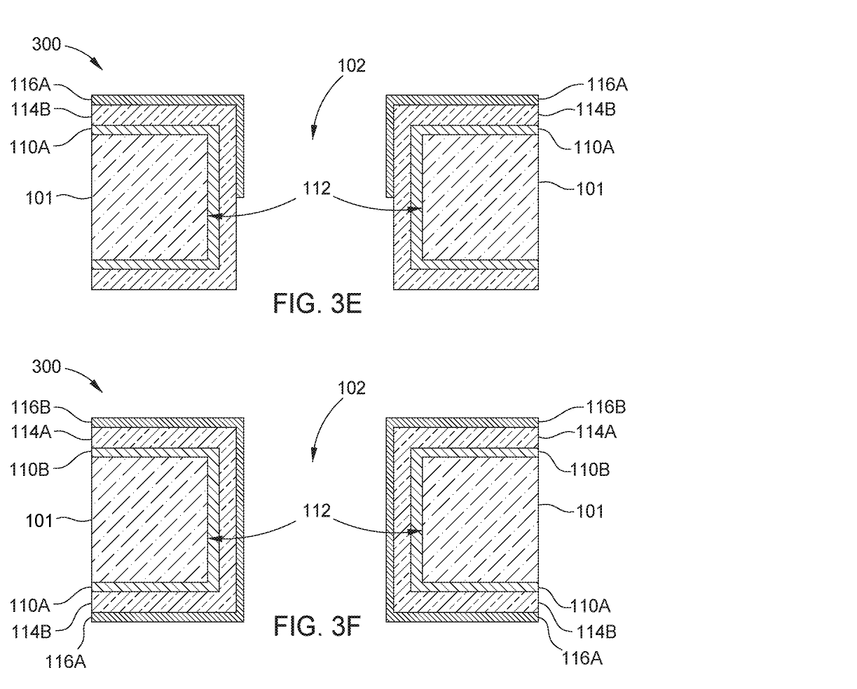

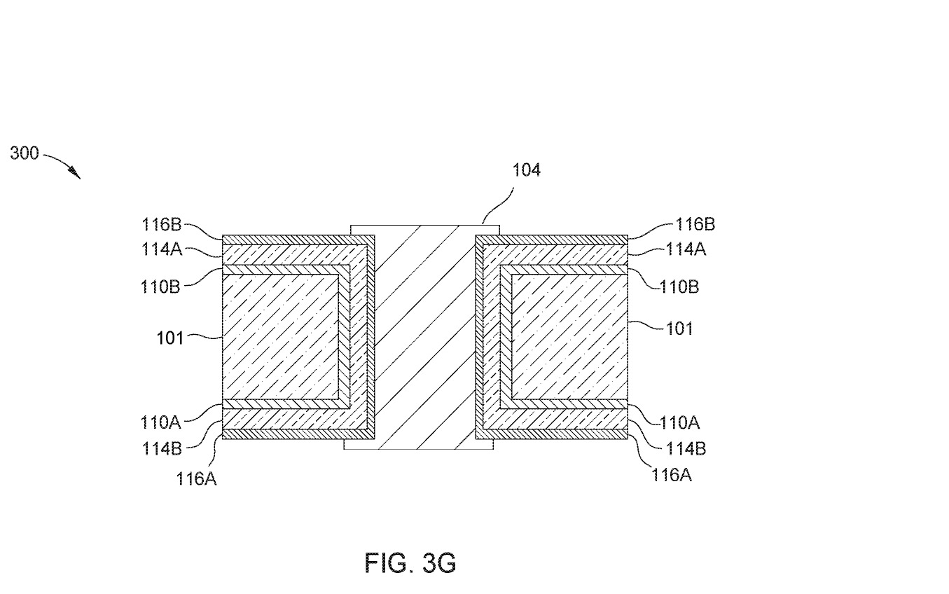

FIG. 2 is a flow diagram of a method 200 for depositing a multi-layer liner in a feature of a substrate, according to certain embodiments. FIGS. 3A – 3G are schematic cross-sectional views of the processing of a substrate 300 during the various operations performed in method 200. In some embodiments, the operations of method 200 for forming a multi-layer liner 109 in a substrate 300 may be performed using a single process chamber or a multi-chamber processing system.

As used in this regard, the term “feature” means any intentional surface irregularity. The shape of the feature can be any suitable shape including, but not limited to, trenches and cylindrical vias. Suitable examples of features include, but are not limited to through vias, which have a generally cylindrical interior surface/sidewall. Other examples of features include without limitation, lines, contact holes, through-holes or other feature definitions utilized in a semiconductor, solar, or other electronic devices, such as high aspect ratio contact plugs. The features can have any suitable aspect ratio (ratio of the depth of the feature to the width of the feature). However, those skilled in the art will understand that the methods described are not limited to through via applications and can be used for other features such as trenches or blind vias.

The method 200 includes operation 201 in which a portion 110A of the first sublayer 110 is formed over the first surface 106 of the substrate 300. As shown, the substrate 300 includes a substrate, such as a glass core 101, having a feature formed therein. For example, the glass core 101 may have a feature such as a via 102 extending therethrough. In some embodiments, the via 102 is a through via that extends through the glass core 101 from a first surface 106 on one side of the glass core 101 to a second surface 108 on the opposite side of the glass core 101. In some embodiments, the portion 110A of the first sublayer 110 formed in operation 201 is disposed over portions of the interior surfaces 112 of the via 102 extending from the first surface 106, as shown in FIG. 3A. In some embodiments, the first sublayer 110 can be formed using one of a chemical vapor deposition (CVD), a plasma enhanced CVD (PECVD), or an atomic layer deposition (ALD) process in which the first sublayer 110 is conformally deposited on the interior surface 112 to line the via 102.

In operation 202, the substrate 300 is flipped, and a remaining portion 110B of the first sublayer 110 is formed over the second surface 108 of the glass core 101. The process performed in operation 202 to form the portion 110B may be the same as the process performed in operation 201 for forming the portion 110A of the first sublayer 110. As shown in FIG. 3B, operation 202 includes forming the portion 110B on interior surfaces 112 of the via 102 extending from the second surface 108 which results in forming the first sublayer 110 lining the entirety of the interior surface 112 of the via 102 from the first surface 106 to the second surface 108. As discussed above, the first sublayer 110 may be deposited to a thickness of between about 5% and about 15% of a thickness of the second sublayer 114 intending to be formed for the multi-layer liner 109. After operation 202, the as deposited first sublayer 110 has a compressive stress between about -500 MPa and about -1500 MPa. In an embodiment, the first sublayer 110 is a silicon nitride film. In other embodiments, the first sublayer 110 may be made of silicon oxynitrde, silicon oxide, silicon carbide, or a metal oxide. In some embodiments, the first sublayer 110 may be of any material that when deposited forms a thin film with the aforementioned compressive stress parameters described herein for the first sublayer 110.

In operation 203, a first portion 114A of the second sublayer 114 is formed over the first sublayer 110 on the second surface 108 of the glass core 101 and in the via 102 of the glass core 101. In some embodiments, as shown in FIG. 3C, operation 203 provides for forming the second sublayer 114 over the portion 110B of the first sublayer 110 inside the via 102. In some embodiments, the second sublayer 114 is a SiOC film formed using one of a chemical vapor deposition (CVD), a plasma enhanced CVD (PECVD), or an atomic layer deposition (ALD) process in which the second sublayer 114 is conformally deposited (grown) on the first sublayer 110 inside the via 102 and on the interior surface 112 . In some embodiments, the second sublayer 114, such as the SiOC film, is formed with a Young’s modulus between about 1 GPa and about 15 GPa. In some embodiments, the second sublayer 114, is formed with some film stress, such as a tensile stress between about 20 MPa and about 70 MPa, such as about 50 MPas, and a compressive stress between about -80 MPa and about -120 MPa, such as about -100 MPa.

In operation 204, the substrate 300 is flipped, and a second portion 114B of the second sublayer 114 is formed over the portion 110A of the first sublayer 110, as shown in FIG. 3D. The process performed in operation 204 may be the same as the process performed in operation 203 when forming the first portion 114A of the second sublayer 114. In some embodiments, which may be combined with other embodiments described herein, the second sublayer 114 is formed with a thickness between about .5 microns and about 5 microns.

In some embodiments, operations 203 and 204 for forming the second sublayer 114 may include the use of a PECVD process in which the substrate 300 is exposed to a plasma generated from a precursor gas mixture comprising Hexamethyldisiloxane (HMDSO) and nitrous oxide (N₂O). In some embodiments, a ratio between the flow rate of the N₂O gas and the HMDSO gas is about between 2:1 and 30:1. In some embodiments, which may be combined with other embodiments described herein, operations 203 and 204 may also include flowing additional additive gases such as H₂ gas at a flow rate between about 30% and 100% of the N2O gas flow rate, NH3 gas at a flow rate between about 20% and about 60% of the N2O gas flow rate, and/or SiH4 gas at a flow rate between about 5% and about 30% of the HMDSO gas flow rate. In some embodiments, the plasma may be generated by applying a high frequency RF power between about .25 W/cm² and about .6W/cm² at a frequency of about 13.56 MHz.

In some embodiments, which may be combined with other embodiments described herein, operations 203 and 204 may be performed at a process temperature between about 100°C and about 350°C. In some embodiments, which may be combined with other embodiments described herein, operations 203 and 204 may be performed at a process pressure between about 0.5 and about 2 Torr.

After operation 204 in which the second sublayer 114 is formed, in some embodiments, an optional operation 205 may be performed in which an annealing process is performed on the second sublayer 114 in a vacuum. In some embodiments, which may be combined with other embodiments herein, the second sublayer 114 is vacuum annealed at an anneal temperature between about 250°C and about 350°C in an ambient N₂ environment. In some embodiments, the vacuum annealing process of operation 205 may be performed for an annealing time between about 30 mins. and about 120 mins. at an annealing pressure between about .2 Torr and about 1 Torr.

In operation 206, a first portion 116A of the third sublayer 116 is formed over the second sublayer 114 on the first surface 106 of the glass core 101 and in the via 102. In some embodiments, as shown in FIG. 3E, operation 206 provides for forming the first portion 116A of the third sublayer 116 on the second portion 114B of the second sublayer 114 inside the via 102. In some embodiments, the third sublayer 116 can be any film having a compressive stress between about -100 MPa and about -800 MPa when deposited on the second sublayer 114. For example, in an embodiment, the third sublayer 116 may be a silicon nitride (SiNx) film layer formed using a PECVD process.

In operation 207, the substrate 300 is flipped, and a second portion 116B of the third sublayer 116 is formed over the first portion 114A of the second sublayer 114 and in the via 102, as shown in FIG. 3F. The process performed in operation 207 may be the same as the process performed in operation 206 when forming the first portion 116A of the third sublayer 116. As shown, operation 207 forms the third sublayer 116 over the entire second sublayer 114 in the via 102.

In some embodiments, which may be combined with other embodiments described herein, the third sublayer 116 is formed with a thickness between about 5% and about 15% of the thickness of the second sublayer 114 as formed on the first sublayer 110. In some embodiments, operation 207 may include performing a buffered oxide wet etch process with an etch rate of less than about 3300 Å/min to control the thickness of the resulting third sublayer 116 formed for the multi-layer liner 109.

To mitigate undesired outgassing of a substance, such as hydrogen (H₂), hydrogen-carbon compounds(CₓH_{y}-), COₓ, etc., from the SiOC film layer (in the case of the SiOC film layer formed for the second sublayer 114), the third sublayer 116 may be a silicon nitride (SiN) film layer formed to also function as a gas barrier. In some embodiments, the SiN film layer of the third sublayer 116 may be formed using a PECVD process from a process gas mixture comprising SiH₄, NH₃, N₂, and H₂ gases. In some embodiments, a percentage of the H₂ gas in the process gas mixture is greater than about 30%. The third sublayer 116 may be formed at a process temperature between about 100°C and about 300°C. In some embodiments, which may be combined with other embodiments described herein, the third sublayer 116 may be formed at a process pressure between about 0.5 and about 2 Torr. In some embodiments, the SiN film layer of the third sublayer 116 may comprise a thickness between about 500 Å and about 4000 Å. In some embodiments, the SiN film layer of the third sublayer 116 may have a compressive stress between about 0 MPa and about -500 MPa.

In some embodiments, the multi-layer liner 109 may be formed in a continuous vacuum environment in which the first sublayer 110, second sublayer 114, and third sublayer 116 are all formed without any breaks in vacuum.

In some embodiments, additional processing operations may be performed after operation 207 but before subsequent operation 208 to form additional sublayers over the third sublayer 116. In an embodiment, additional sublayers with materials and parameters corresponding to the second sublayer 114 and third sublayer 116 may be further added for the multi-layer liner 109. The additional sublayers may be formed similarly to operations 203-207 performed for forming the second sublayer 114 and third sublayer 116. For example, a fourth sublayer similar to the second sublayer 114 may subsequently be formed over the third sublayer 116, and a fifth sublayer similar to the third sublayer 116 may then be formed over the fourth sublayer. In some embodiments, the multi-layer liner 109 may therefore include more than three sublayers, such as five sublayers, seven sublayers, and nine sublayers.

In operation 208, after the multi-layer liner 109 is formed in the via 102, a conductive layer is deposited in the via 102 over the multi-layer liner 109 to form the interconnect structure 104, as shown in FIG. 3G. In alternate embodiments, the conductive layer may be a seed layer, a barrier layer, an adhesion layer, or any combination thereof. In such embodiments, operation 208 also includes depositing a second conductive layer 120 over the conductive layer. Examples of the conductive materials that may be used for each of the conductive layers for forming the interconnect structure 104 may include, but are not limited to, metals, e.g., copper, tungsten, tantalum, titanium, hafnium, zirconium, aluminum, silver, tin, lead, metal alloys, titanium nitride, tantalum nitride, metal carbides, e.g., hafnium carbide, zirconium carbide, titanium carbide, tantalum carbide, aluminum carbide, other conductive materials, or any combination thereof. In an embodiment, the conductive layer is a copper layer.

Each of the seed layer and/or conductive layer can be deposited using one of conductive layer deposition techniques, e.g., electroless plating, electroplating, sputtering, chemical vapor deposition (CVD), metalorganic chemical vapor deposition (MOCVD), atomic layer deposition (ALD), or any other conductive layer deposition technique known to one of ordinary skill in the art of electronic device manufacturing.

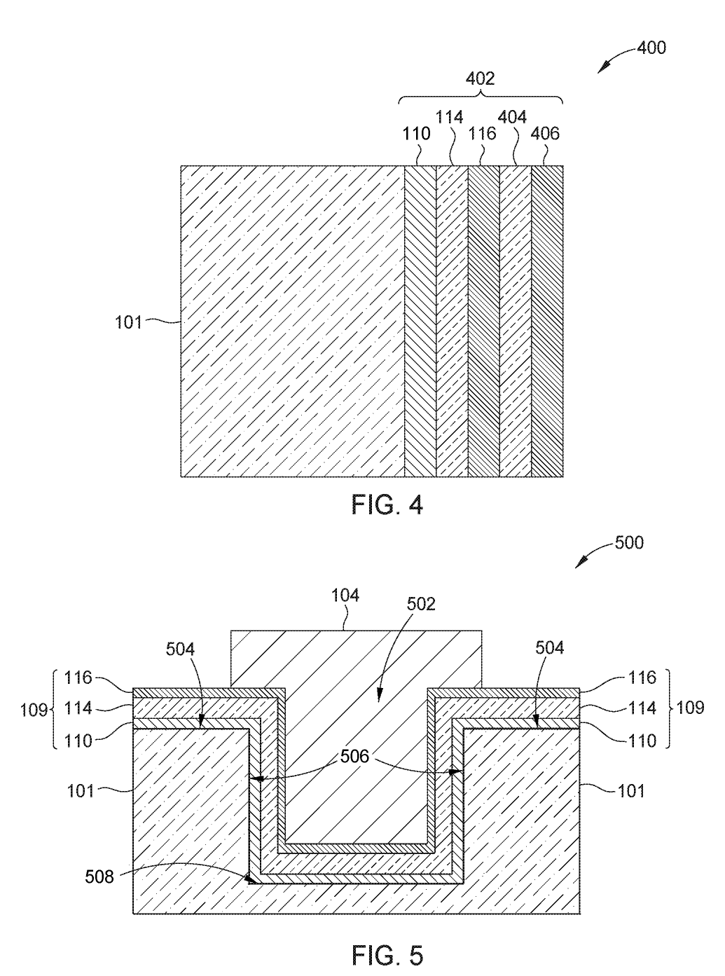

FIG. 4 is a schematic cross-sectional view of a portion of a substrate 400 illustrating a multi-layer liner 402 formed on a glass core 101, according to certain embodiments. In an embodiment, the multi-layer liner 402 includes the first sublayer 110, the second sublayer 114, and the third sublayer 116. In some embodiments, which may be combined with other embodiments described herein, the multi-layer liner 402 also includes a fourth sublayer 404 disposed over the third sublayer 116 and a fifth sublayer 406 disposed over the fourth sublayer 404. In an embodiment, the fourth sublayer 404 can be similar or the same material as the second sublayer 114, for example, the fourth sublayer 404 may be a film layer formed with a Young’s modulus between about 1 GPa and about 15 GPa, such as a SiOC film layer. In some embodiments, the fourth sublayer 404 may be formed with some film stress, such as a tensile stress between about 20 MPa and about 70 MPa, such as about 50 MPa, and a compressive stress between about -80 MPa and about -120 MPa, such as about -100 MPa. The fifth sublayer 406 can be similar or the same material as the third sublayer 116, for example, the fifth sublayer 406 can be any film having a compressive stress between about -100 MPa and about -800 MPa when deposited on the fourth sublayer 404. In an embodiment, which may be combined with other embodiments described herein, the fifth sublayer 406 may be a silicon nitride (SiNx) film layer, silicon carbide (SiC) film layer, or a silicon oxide (SiO) film layer.

FIG. 5 is a schematic cross-sectional view of a substrate 500 illustrating the multi-layer liner 109 and the interconnect structure 104 formed in a via 502 extending partially through a glass core 101 of the substrate 500, according to certain embodiments. In some embodiments, the via 502 (shown filled with the interconnect structure 104) is a vertical interconnect access or hole extending through a portion of the glass core 101. In an embodiment, the via 502 is formed in a top surface 504 of the glass core 101 and extends along sidewalls 506 in the glass core 101 to a base 508. In some embodiments, a diameter d of the via 502 may be between about 5 microns and about 150 microns.

The interconnect structure 104 and the multi-layer liner 109 may be the same or similar to the interconnect structure 104 and the multi-layer liner 109 discussed above with reference to FIG. 1. The interconnect structure 104 may be a vertical conductive copper (Cu) structure for electrically connecting layers within the glass core 101 of the substrate 500. The multi-layer liner 109 lining the via 502 is disposed between the glass core 101 and the interconnect structure 104 along both the sidewalls 506 and the base 508. In some embodiments, the multi-layer liner 109 similarly includes the first sublayer 110 in contact with the sidewalls 506 and base 508 of the via 502 along the glass core 101, and the second sublayer 114 is disposed between the first sublayer 110 and the third sublayer 116 in contact with the interconnect structure 104.

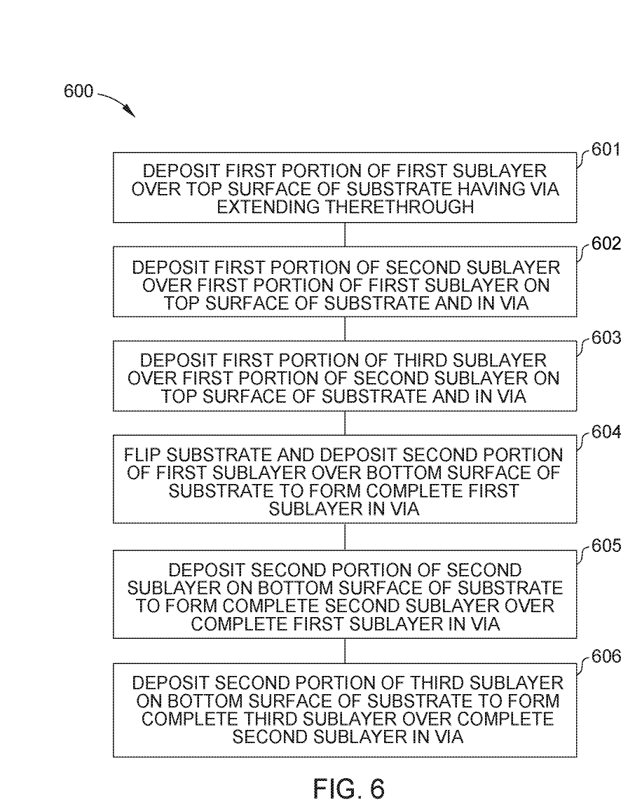

FIG. 6 is a flow diagram of a method 600 for depositing a multi-layer liner in a feature of a substrate, according to certain embodiments. In an embodiment, the substrate may be a glass core substrate. In an embodiment, the feature may be a via extending from a top surface of the substrate. In some embodiments, method 600 for depositing the multi-layer liner may be performed using a single process chamber.

In some embodiments, the operations of method 600 may be used for forming the multi-layer liner 109 in the via 102 of the substrate 100 shown in FIG. 1. In an embodiment, method 600 begins with operation 601 in which the portion 110A of the first sublayer 110 is formed over the first surface 106 of the substrate 100 and on a portion of the interior surface 112 of the via 102 in the substrate 100. In some embodiments, the portion 110A of the first sublayer 110 can be formed using one of a chemical vapor deposition (CVD), a plasma enhanced CVD (PECVD), or an atomic layer deposition (ALD) process in which the first sublayer 110 is conformally deposited (grown) on the interior surface 112 to line the via 102.

In operation 602, the first portion 114A of the second sublayer 114 is formed on the first surface 106 of the substrate 100 over the portion 110A of the first sublayer 110. In an embodiment, the first surface 106 may correspond to a top surface of the substrate 100. In some embodiments, the first portion 114A of the second sublayer 114 is a SiOC film formed using one of a chemical vapor deposition (CVD), a plasma enhanced CVD (PECVD), or an atomic layer deposition (ALD) process in which the second sublayer 114 is conformally deposited (grown) on the portion 110A of the first sublayer 110 inside the via 102.

In operation 603, the first portion 116A of the third sublayer 116 is formed on the first surface 106 of the substrate 100 over the first portion114A of the second sublayer 114 and in the via 102 of the substrate 100. Operation 603 provides for forming the first portion 116A of the third sublayer 116 on the first portion 114A of the second sublayer 114 inside the via 102. In some embodiments, the first portion 116A of the third sublayer 116 can be any film having a compressive stress between about -100 MPa and about -800 MPa when deposited on the second sublayer 114. For example, in an embodiment, the first portion 116A of the third sublayer 116 may be a silicon nitride (SiNx) film layer formed using a PECVD process.

In some embodiments, operations 601-603 may be performed to form the multi-layer liner 109 in a blind via, such as the via 502 in substrate 500 shown in FIG. 5.

In operation 604, the substrate 100 is flipped and a remaining portion 110B of the first sublayer 110 is formed over the second surface 108 of the substrate 100. In an embodiment, the second surface 108 may correspond to a bottom surface of the substrate 100. Operation 604 deposits the portion 110B in the via 102 of the substrate 100 near the second surface 108. The process performed in operation 604 may be the same or similar to the process performed in operation 601. Operation 604 results in completing the first sublayer 110 of the multi-layer liner 109 along the entirety of the interior surface 112 of the via 102.

Thereafter, in operation 605, a second portion114B of the second sublayer 114 is deposited on the second surface 108 of the substrate 100 over the portion 110B of the first sublayer 110. Operation 605 includes forming the second portion 114B over the first sublayer 110 in the via 102 of the substrate 100. The process performed in operation 605 may be the same or similar to the process performed in operation 602 to form and complete the second sublayer 114 of the multi-layer liner 109.

In operation 606, the second portion 116B of the third sublayer 116 is formed on the second surface 108 of the substrate 100 over the second portion 114B of the second sublayer 114. The process performed in operation 606 may be the same or similar to the process performed in operation 603 when forming the first portion 116A of the third sublayer 116. Operation 606 results in forming and completing the third sublayer 116 of the multi-layer liner 109 in the via 102.

Method 600 provides for forming the multi-layer liner 109 in the via 102 with only a single flip of the substrate 100, resulting in increased throughput when processing the substrate 100.

As discussed above, the first sublayer 110 may be deposited to a thickness of between about 5% and about 15% of the thickness of the second sublayer 114 intending to be formed for the multi-layer liner 109. The as-deposited first sublayer 110 has a compressive stress between about -500 MPa and about -1500 MPa. In an embodiment, the first sublayer 110 is a silicon nitride film. In other embodiments, the first sublayer 110 may be a silicon oxide or a silicon carbide film. In some embodiments, the first sublayer 110 may be of any material that when deposited, forms a thin film with the requisite compressive stress described herein for the first sublayer 110.

In some embodiments, the second sublayer 114 may be a SiOC film formed with a Young’s modulus between about 1 GPa and about 15 GPa. In some embodiments, the second sublayer 114, is formed with some film stress, such as a tensile stress between about 20 MPa and about 70 MPa, such as about 50 MPas, and a compressive stress between about -80 MPa and about -120 MPa, such as about -100 MPa. In some embodiments, which may be combined with other embodiments described herein, the second sublayer 114 is formed with a thickness between about .5 microns and about 5 microns.

In some embodiments, the third sublayer 116 can be any film having a compressive stress between about -100 MPa and about -800 MPa when deposited on the second sublayer 114. For example, in an embodiment, the third sublayer 116 may be a silicon nitride (SiNx) film layer formed using a PECVD process. In some embodiments, which may be combined with other embodiments described herein, the third sublayer 116 is formed with a thickness between about 5% and about 15% of the thickness of the second sublayer 114 as formed on the first sublayer 110.

In summation, embodiments herein relate to the fabrication of through glass vias (TGV) in glass substrates. In an embodiment, the methods described herein provide for forming a multi-layer liner in through glass vias to for buffering the mechanical stress between an interconnect structure formed therein and the glass core substrate due to CTE mismatch. The methods described herein reduce the risk of cracking of the glass core substrate during panel level packaging processes. Benefits of the present disclosure also provide for preventing delamination of conducting layer for forming interconnect structures in TGVs which can increase reliability of resulting formed devices.

What is claimed is:

1. A method for fabricating a multi-layer liner, comprising:
depositing a first sublayer over a surface of a substrate comprising a glass core and a via extending therethrough, wherein the first sublayer is disposed over sidewalls of the via and comprises a compressive stress between about -500 MPa and about -1500 MPa;
depositing a second sublayer over the first sublayer inside the via, wherein the second sublayer comprises a Young’s modulus between about 1 GPa and about 15 GPa; and
depositing a third sublayer over the second sublayer inside the via, wherein the third sublayer comprises a stress between about -100 MPa and about -800 MPa compressive stress.

2. The method of claim 1, wherein the second sublayer comprises a thickness between about .5 microns and about 5 microns.

3. The method of claim 2, wherein the first sublayer comprises a thickness between about 5% and about 15% of the thickness of the second sublayer.

4. The method of claim 2, wherein the third sublayer comprises a thickness between about 5% and about 15% of the thickness of the second sublayer.

5. The method of claim 1, further comprising depositing an interconnect structure in the via after the multi-layer liner is formed, wherein the multi-layer liner is disposed between the interconnect structure and the glass core of the substrate.

6. The method of claim 1, wherein the first sublayer comprises silicon nitride (SiNx), silicon oxynitride (SiON), silicon carbide (SiC), silicon oxide (SiO), a metal oxide (e.g., AlOx), or combinations thereof.

7. The method of claim 1, wherein the second sublayer comprises silicon oxycarbide (SiOC).

8. The method of claim 1, wherein the third sublayer comprises silicon nitride (SiNx), silicon oxynitride (SiON), silicon carbide (SiC), silicon oxide (SiO), a metal oxide(e.g., AlOx), or combinations thereof.

9. The method of claim 1, wherein the second sublayer comprises a tensile stress of about 50 MPa and a compressive stress of about -100 MPa.

10. The method of claim 1, wherein forming the second sublayer comprises performing a PECVD process using a precursor gas mixture comprising a Hexamethyldisiloxane (HMDSO) gas and a nitrous oxide (N₂O) gas, wherein a ratio between a flow rate of the N₂O gas and a flow rate of the HMDSO gas is between about 2:1 and about 30:1.

11. The method of claim 1, wherein the via comprises a diameter between about .5 microns and about 150 microns.

12. The method of claim 1, wherein forming the first sublayer comprises:
depositing a first portion of the first sublayer over a top surface of the substrate and on a portion of interior surfaces of the via;
flipping the substrate; and
depositing a second portion of the first sublayer over a bottom surface of the substrate and on a remaining portion of interior surfaces of the via.

13. The method of claim 1, wherein forming the second sublayer comprises:
depositing a first portion of the second sublayer over the first sublayer on a top surface of the substrate and on a portion of interior surfaces of the via;
flipping the substrate; and
depositing a second portion of the second sublayer over the first sublayer on a bottom surface of the substrate and on a remaining portion of interior surfaces of the via.

14. The method of claim 1, wherein forming the third sublayer comprises:
depositing a first portion of the third sublayer over the second sublayer on a top surface of the substrate and on a portion of interior surfaces of the via;
flipping the substrate; and
depositing a second portion of the third sublayer over the second sublayer on a bottom surface of the substrate and on a remaining portion of interior surfaces of the via.

15. A method for fabricating a multi-layer liner, comprising:
depositing a first portion of a first sublayer over a top surface of a substrate, the substrate comprising a via extending between the top surface and a bottom surface of a glass core;
flipping the substrate;
depositing a second portion of the first sublayer over the bottom surface of the substrate and in the via, wherein the first sublayer comprises a compressive stress between about -500 MPa and about -1500 MPa;
depositing a first portion of a second sublayer over the second portion of the first sublayer;
flipping the substrate;
depositing a second portion of the second sublayer over the first portion of the first sublayer on the substrate and in the via, wherein the second sublayer comprises a Young’s modulus between about 1 GPa and about 15 GPa;
depositing a first portion of a third sublayer over the second portion of the second sublayer on the substrate;
flipping the substrate; and
depositing a second portion of the third sublayer over the first portion of the second sublayer on the substrate and in the via, wherein the third sublayer comprises a compressive stress between about -100 MPa and about -800 MPa.

16. The method of claim 15, further comprising depositing a seed layer over the multi-layer liner in the via, and depositing a conductive material over the seed layer to form an interconnect structure, wherein the multi-layer liner is disposed between the interconnect structure and the glass core of the substrate.

17. A semiconductor substrate, comprising:
a glass core having a via extending therethrough;
a multi-layer liner comprising:
a first sublayer disposed over an interior surface of the via, wherein the first sublayer comprises a compressive stress between about -500 MPa and about -1500 MPa;
a second sublayer disposed over the first sublayer, wherein the second sublayer comprises a Young’s modulus between about 1 GPa and about 15 GPa; and
a third sublayer disposed over the second sublayer, wherein the third sublayer comprises a compressive stress between about -100 MPa and about -800 MPa; and
a conductive interconnect structure formed in the via, wherein the multi-layer liner is disposed between the glass core and the conductive interconnect structure.

18. The semiconductor substrate of claim 17, wherein the second sublayer comprises a thickness between about .5 microns and about 5 microns.

19. The semiconductor substrate of claim 18, wherein each of the first sublayer and third sublayer comprises a thickness between about 5% and about 15% of the thickness of the second sublayer.

20. The semiconductor substrate of claim 17, wherein the second sublayer is made of silicon oxycarbide (SiOC) and comprises a tensile stress of about 50 MPa, and a compressive stress of about -100 MPa.
